(19) United States
(12) Patent Application Publication
(10) Pub. No.: US 2001/0050550 A1
(43) Pub. Date: Dec. 13, 2001

(54) High frequency component, communication apparatus, and method for measuring characteristics of high frequency component

(76) Inventors: Norio Yoshida, Otsu-shi (JP); Takahiro Watanabe, Shiga-ken (JP); Tomonori Ito, Shiga-ken (JP)

Correspondence Address: Keating & Bennett LLP, Suite 312, 10400 Eaton Place, Fairfax, VA, 22030, US

(21) Appl. No.: 09/795,179

(22) Filed: Feb. 28, 2001

(30) Foreign Application Priority Data
Feb. 29, 2000 (JP) 2000-053313

(51) Int. Cl. G01R 23/12

(52) U.S. Cl. 324/76.53

(57) ABSTRACT

A high frequency component is constructed such that the characteristics of a high frequency circuit that cannot be measured only by an outwardly extending terminal electrode are easily measured at the final-product stage. In the high frequency component, a substrate has an electrode pattern provided including a signal measuring electrode pad. Additionally, chip components are mounted on the substrate. A metal cover has a hole provided near the signal measuring electrode pad. Through the hole, a probe of a measuring apparatus is inserted from the outside to abut with the electrode pad. With the arrangement, a voltage signal obtained at a predetermined point of the high frequency circuit is measured.

### BACKGROUND OF THE INVENTION

1. Field of the Invention

The present invention relates to high frequency components having metal covers, communication apparatuses incorporating the high frequency components, and methods for measuring the characteristics of the high frequency components.

2. Description of the Related Art

In a conventional high frequency component such as a voltage-controlled oscillator or a PLL module used in a mobile phone or other suitable device, various types of chip components are mounted on a substrate having an electrode pattern provided thereon. Additionally, a metal cover is attached over the substrate to cover the chip components provided on the substrate.

Each of FIGS. 6A and 6B shows a conventional high frequency component. FIG. 6A is a perspective view of the high frequency component, and FIG. 6B is a sectional view thereof. In both figures, the reference numeral 1 denotes a ceramic substrate. On an upper surface of the substrate 1 various types of chip components are mounted. A metal cover 2 is attached over the substrate 1 such that the cover 2 covers the upper surface of the substrate 1 on which the components are mounted.

As shown above, in the conventional high frequency component, a high frequency circuit is provided on the substrate having a top portion is covered by the metal cover. When the characteristics of the high frequency circuit are measured regarding a signal other than the signal of an outwardly extending terminal electrode, the measurement of a voltage is performed by allowing a probe of a measuring apparatus to contact an electrode pad on the substrate before covering the top of the substrate with the metal cover.

However, after measuring the characteristics of the component, when the metal cover is attached over the substrate to produce the high frequency component as a final product, a shielded space is created over the upper surface of the substrate by the metal cover. As a result, the characteristics of the high frequency component are changed due to the influence of a stray capacitance and electromagnetic coupling occurring between the metal cover and the components and the electrode pattern provided on the substrate. Thus, the obtained characteristics deviate from a desired characteristic range, and this is a factor by which the ratio of non-defective products to defective products is reduced, i.e., output is deteriorated.

To prevent these problems, it is necessary to obtain information about how the characteristics change before and after covering with the metal cover to determine the range of measured values necessary to obtain desirable characteristics. However, it is impossible to accurately predict how the characteristics change before and after covering with the metal cover. Thus, the ratio of non-defective products to defective products cannot be sufficiently increased.

### SUMMARY OF THE INVENTION

To overcome the above-described problems with the prior art, preferred embodiments of the present invention provide a method for easily measuring the characteristics of a high frequency circuit, which cannot be measured by an outwardly led-out terminal electrode, at the final product stage. Additionally, another preferred embodiment of the present invention provides a communication apparatus incorporating a high frequency component having desired characteristics.

According to preferred embodiments of the present invention, a high frequency component includes a substrate, high frequency circuit components mounted on the substrate, a signal measuring electrode pad disposed on the substrate, a metal cover for covering the top of the substrate, and a hole provided in the metal cover, which is disposed in the vicinity of the signal measuring electrode pad.

In this arrangement, while the metal cover is attached over the substrate, the signal measuring electrode pad is arranged on the substrate such that the electrode pad is in contact with a probe of a measuring apparatus inserted through the hole of the metal cover. In other words, a voltage signal in a predetermined position of the high frequency circuit is measured at the final product stage.

In addition, in the high frequency component of preferred embodiments of the present invention, the diameter or width of the hole is preferably greater than the diameter or width of the signal measuring electrode pad and equal to or less than a length corresponding to about 1/4 wavelength of a frequency used in the component. This arrangement sufficiently suppresses the radiation or incidence of an electromagnetic wave of the used frequency band or a higher frequency band through the hole provided in the metal cover. As a result, the shielding effect of the metal cover is maintained.

According to preferred embodiments of the present invention, a communication apparatus is provided including the above-described high frequency component. In this communication apparatus, for example, the high frequency component is used as a high-frequency signal oscillator or a filter.

According to preferred embodiments of the present invention, a method for measuring the characteristics of the above high frequency component is provided. In this method, the probe is inserted in the hole of the metal cover of the high frequency component to measure a voltage at the signal measuring electrode pad.

Other features, elements, advantages and characteristics of the present invention will become more apparent from the detailed description of preferred embodiments thereof with reference to the attached drawings.

### BRIEF DESCRIPTION OF THE DRAWINGS

FIGS. 1A and 1B are a perspective view and a sectional view of a high frequency component according to a first preferred embodiment of the present invention;

FIG. 2 is a partial top view of the high frequency component according to the first preferred embodiment of the present invention;

FIG. 3 is a circuit diagram of the main portion of the high frequency component;

FIG. 4 is a chart showing a method for measuring the characteristics of a high frequency component according to a second preferred embodiment of the present invention;

FIG. 5 is a block diagram showing the structure of a communication apparatus according to a third preferred embodiment of the present invention; and

FIGS. 6A and 6B are a perspective view and a sectional view showing the structure of a conventional high frequency component.

### DETAILED DESCRIPTION OF PREFERRED EMBODIMENTS

FIGS. 1A and 1B to FIG. 3 illustrate the structure of a PLL module as a high frequency component according to a first preferred embodiment of present invention.

FIG. 1A is a perspective view of the PLL module, and FIG. 1B is a sectional view thereof. In the PLL module, an electrode pattern is provided on an upper surface of a ceramic substrate 1, and a plurality of chip components are mounted thereon. In a portion of a metal cover 2, a hole 4 is provided in the vicinity of a signal measuring electrode pad 3.

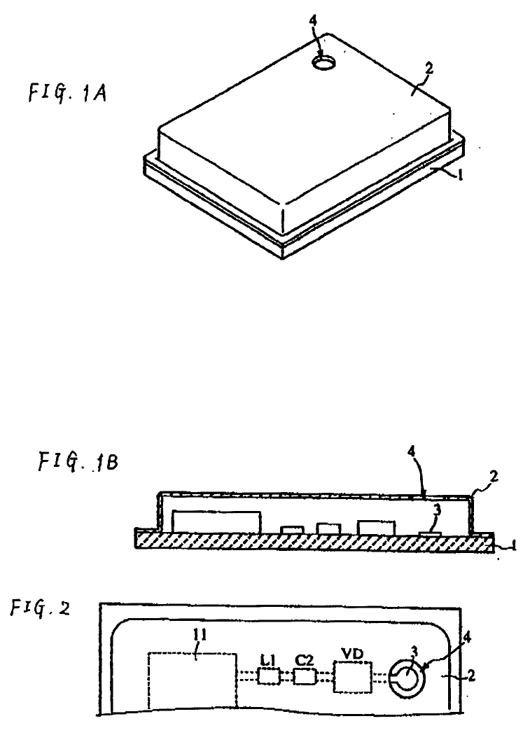

FIG. 2 is a partial top view of the PLL module. The inner diameter of the hole 4 is greater than the diameter of the electrode pad 3 and is preferably substantially equal to or less than a length corresponding to about ¼ wavelength of a frequency used in the component. For example, when the diameter of the electrode pad 3 is about 5 mm and the used frequency is 2.4 GHz, the diameter of the hole 4 is less than a length of about 31 mm corresponding to the about ¼ wavelength.

As shown above, the diameter of the hole 4 is greater than the electrode pad 3. With this arrangement, even if there is a slight positional deviation between the electrode pad 3 and the hole 4 of the metal cover 2, the probe of a measuring apparatus is not short-circuited to the metal cover. In addition, the position of the electrode pad 3 viewed through the hole 4 can be accurately determined. As a result, the probe appropriately abuts the approximate center of the electrode pad 3.

In addition, the width of the hole 4 provided in the metal cover 2 is equal to or less than a length corresponding to about ¼ wavelength of a used frequency. This arrangement suppresses unnecessary radiation of an electromagnetic wave to the outside and incidence thereof from the outside to the inside of the high frequency component in the used frequency band or a higher frequency band. As a result, the shielding effect of the metal cover 2 is effectively maintained.

In this preferred embodiment, although the hole 4 preferably has a substantially round shape, a substantially rectangular hole may also be provided. In the case of the substantially rectangular hole, the vertical and horizontal widths of the hole are greater than the dimension of the electrode pad 3 and are preferably substantially equal to or less than a length corresponding to about ¼ wavelength of a used frequency.

FIG. 3 is a circuit diagram of the main portion of the PLL module. In this figure, the reference numeral 11 denotes a high frequency integrated circuit (IC). An amplifying circuit included in the high frequency IC 11 and a resonance circuit which includes a chip inductor L1, a chip capacitor C2, and a varactor diode VD define a voltage-controlled oscillation circuit (VCO). A loop-filter 12 is disposed at the output end of the PLL circuit of the high frequency IC 11. The output end of the loop filter 12 is connected to the cathode of the varactor diode VD. The output end of a modulating circuit included in the high frequency IC 11 is connected to the anode of the varactor diode VD via a resistance voltage divider circuit 13. Furthermore, a power supply circuit included in the high frequency IC 11 is connected to the chip inductor L1 via a capacitor C1, a resistor R1, and a choke coil L2. With this arrangement, a power supply voltage is applied to the amplifying circuit.

The PLL circuit performs a phase comparison between a reference frequency signal supplied from the outside and an oscillation signal sent from the oscillation circuit. Then, the PLL circuit transmits a phase error signal to the varactor diode VD via the loop filter 12 to change the electrostatic capacitance of the varactor diode VD to control the oscillation frequency. The modulating circuit controls a voltage applied to the varactor diode VD to modulate the oscillation frequency.

The reference numerals 11, L1, C2, and VD shown in FIG. 2 correspond to the high frequency IC 11, the chip inductor L1, the chip capacitor C2, and the varactor diode VD shown in FIG. 3. The electrode pad 3 shown in FIGS. 1 to 3 is an electrode for measuring a cathode potential at the varactor diode VD, that is, a controlling voltage output from the PLL circuit via the loop filter 12. The controlling voltage is measured by abutting a probe 5 with the electrode pad 3.

As shown above, by measuring the controlling voltage applied to the varactor diode from the PLL module, the relationship between the oscillation frequency and the controlling voltage of the completed product is measured.

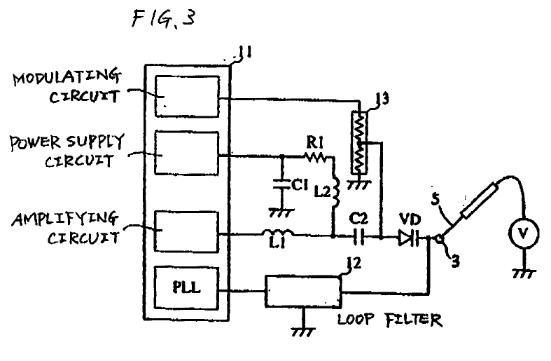

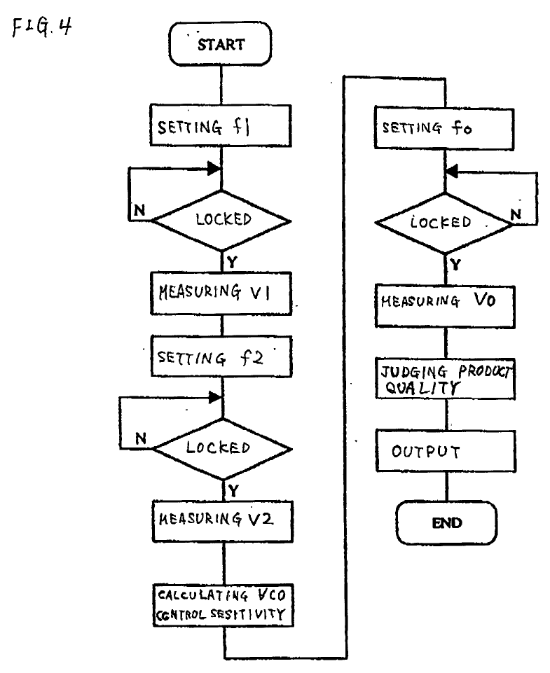

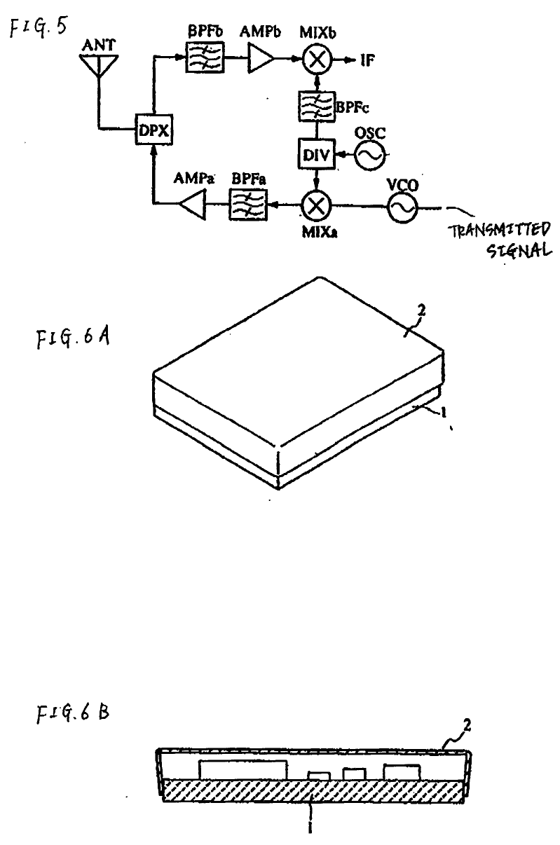

Next, as a second preferred embodiment of the present invention, a method for measuring the characteristics of a PLL module will be explained with reference to a flowchart shown in FIG. 4.

The PLL module used in the second preferred embodiment is a high frequency component shown in each of FIGS. 1 to 3 (the PLL module). First, controlling data is sent to the high frequency IC 11 such that the oscillation frequency of the PLL module shown in FIG. 3 is set at f1. The high frequency IC 11 determines a frequency division ratio with respect to a reference frequency signal based on the controlling data. When the PLL module is in a locked status, a voltage V1 at the point in time is measured by the probe 5. Sequentially, controlling data is sent to the high frequency IC 11 to set the oscillation frequency at f2. Then, when the PLL module is in the locked status, a voltage V2 is measured by the probe 5. Next, a VCO control sensitivity is obtained as a value of (f2−f1)/(V2−V1). In addition, controlling data is supplied to the high frequency IC 11 to set the oscillation frequency to a desired frequency fo within the range from f1 to f2, and a voltage Vo is measured when the PLL module is locked. After this, whether or not the VCO control sensitivity comes within a desired standard range and whether or not the voltage Vo comes within a desired standard range is determined, and the obtained results are output.

Measurement was actually performed using the PLL module having a frequency in the 2.4 GHz band. For example, when f1 was set at 2400 MHz, V1 was set at 0.7 V, and f2 was set at 2500 MHz, V2 was 1.7 V. As a result, the VCO control sensitivity was obtained by the equation (2500-2400)/(1.7-0.7)=100 [MHz/V]. In the conventional PLL module at the final product stage, it was impossible to measure such a voltage and a VCO control sensitivity as shown above.

With the above arrangement, at the finished product stage, product quality, that is, whether the product is defective or not can be precisely and easily determined.

Next, the structure of a communication apparatus according to a third preferred embodiment of the present invention will be illustrated with reference to FIG. 5. In this figure, the reference character ANT denotes a transmission/reception antenna, the reference character DPX denotes a duplexer, and the reference characters BPFa, BPFb, and BPFc denote band pass filters. The reference characters AMPa and AMPb denote amplifying circuits, the reference characters MIXa and MIXb denote mixers. The reference character OSC denotes an oscillator, and the reference character DIV denotes a power divider. The reference character VCO denotes a voltage-controlled oscillator modulating an oscillation frequency with a signal corresponding to a transmitted signal (transmitted data).

The MIXa modulates a frequency signal output from the DIV with a modulation signal. The BPFa passes only signals of a transmitted frequency band and the AMPa performs power-amplification of the signals to transmit from the ANT via the DPX. The BPFb passes only signals of a received frequency band among the signals supplied from the DPX, and the AMPb amplifies the signals. The MIXb mixes a frequency signal output from the BPFC with the received signal to output an intermediate frequency signal IF.

The high frequency component shown in each of FIGS. 1A and 1B to FIG. 4 is used as a high frequency component such as a VCO or a filter shown in FIG. 5, in which high frequency circuit components are mounted on a substrate and a metal cover is attached over the substrate. With this arrangement, a communication apparatus is provided by using the high frequency component in which characteristics inside a high frequency circuit, which cannot be measured only by an outwardly exposed terminal electrode, fall within a predetermined range. Thus, after the assembly, the expected characteristics are achieved without fail.

Furthermore, where the high frequency component is disposed on the circuit substrate of the communication apparatus, through the hole of the metal cover, a voltage at a desired point inside the high frequency component is measured. Thus, the above measurement enables the determination of whether or not the high frequency component as a measured target acts with the desired characteristics when the communication apparatus as a final product is in operation.

In this manner, the communication apparatus incorporates a high frequency component having very stable characteristics.

As described above, in the high frequency component and the communication apparatus including the same according to various preferred embodiments of the present invention, while the metal cover is attached over the substrate, the signal measuring electrode pad on the substrate is in contact with the probe of a measuring apparatus through the hole of the metal cover. As a result, at the finished product stage, a voltage signal in a desired position of the high frequency circuit is measured.

In addition, radiation or incidence of electromagnetic waves of a used frequency band and a higher frequency band is effectively suppressed through the hole provided in the metal cover. Thus, the shielding effect of the metal cover is effectively maintained.

According to preferred embodiments of the present invention, a high frequency circuit is provided including, for example, a high-frequency signal oscillator, a filter, and other suitable device, by using high frequency components having desired characteristics. As a result, a communication apparatus having predetermined communication capabilities can be easily obtained.

While the present invention has particularly shown and described with reference to the preferred embodiments thereof, it will be understood by those skilled in the art that the foregoing and other changes in form and details can be made therein without departing from the spirit and scope of the invention.

What is claimed is:

1. A high frequency component comprising:
a substrate;
high frequency circuit components mounted on the substrate;
a signal measuring electrode pad disposed on the substrate;
a metal cover covering the top of the substrate; and
a hole provided in the metal cover, which is disposed in the vicinity of the signal measuring electrode pad.

2. A high frequency component according to claim 1, wherein the diameter or width of the hole is greater than the diameter or width of the signal measuring electrode pad and are substantially equal to or less than a length corresponding to ¼ wavelength of a used frequency.

3. A high frequency component according to claim 1, wherein said hole is substantially round.

4. A high frequency component according to claim 1, wherein said hole is substantially rectangular.

5. A high frequency component according to claim 1, wherein said high frequency component is a PLL module.

6. A communication apparatus comprising the high frequency component according to claim 1.

7. A method for measuring the characteristics of a high frequency component comprising steps of:
inserting a probe in the hole of the metal cover of the high frequency component according to claim 1; and
measuring a voltage at the signal measuring electrode pad.

8. A method for measuring the characteristics of a high frequency component according to claim 7, wherein the diameter or width of the hole is greater than the diameter or width of the signal measuring electrode pad and are substantially equal to or less than a length corresponding to ¼ wavelength of a used frequency.

9. A method for measuring the characteristics of a high frequency component according to claim 7, wherein said hole is substantially round.

10. A method for measuring the characteristics of a high frequency component according to claim 7, wherein said hole is substantially rectangular.

11. A method for measuring the characteristics of a high frequency component according to claim 7, wherein said high frequency component is a PLL module.
